(19) United States
(12) Patent Application Publication
(10) Pub. No.: US 2025/0194023 A1
(43) Pub. Date: Jun. 12, 2025

(54) POWER EFFICIENT SHOCK DETECTOR

(71) Applicant: Dell Products L.P., Round Rock, TX (US)

(72) Inventors: Craig L. CHAIKEN, Pflugerville, TX (US); Hong-Ling CHEN, Taoyuan City (TW); Hou-Chun WANG, Linkou Dist. (TW)

(73) Assignee: Dell Products L.P., Round Rock, TX (US)

(21) Appl. No.: 18/531,279

(22) Filed: Dec. 6, 2023

(51) Int. Cl. H05K 5/00; G06F 1/18; G06F 3/06

(52) U.S. Cl. CPC H05K 5/0056; G06F 1/182; G06F 3/0619

(57) ABSTRACT

An information handling system may include a circuit board, a shock detector mounted on the circuit board, and a detection circuit electrically coupled to the shock detector. The shock detector may be configured to complete an electrical circuit in a first state in an absence of a threshold mechanical force applied to the information handling system and to have an impedance discontinuity in a second state in a presence of the threshold mechanical force. The detection circuit may be configured to detect whether the impedance discontinuity exists.

### TECHNICAL FIELD

The present disclosure relates in general to information handling systems, and more particularly to detecting mechanical shocks to an information handling system in a power-efficient manner.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems often employ one or more circuit boards. A circuit board may broadly refer to a printed circuit board (PCB), printed wiring board (PWB), printed wiring assembly (PWA) etched wiring board, and/or any other board or similar physical structure operable to mechanically support and electrically couple electronic components (e.g., packaged integrated circuits, slot connectors, etc.). A circuit board may be used to implement a motherboard, a riser card, a mezzanine card, a paddle card, and/or many other components of an information handling system. Information handling systems also often include display devices, either communicatively coupled to an information handling system via a cable or integrated within the information handling system enclosure itself (e.g., in the case of a notebook or tablet computer).

One problem sometimes experienced by information handling systems is damage to display devices or internal components caused by mechanical shock events, which may occur due to user mishandling. User mishandling and subsequent mechanical shock events may occur when the information system is in a sleep state. Traditional shock sensors consume excessive power or are unable to detect a shock event when the information handling system is powered off (e.g, in a S5 sleep state as defined by Advanced Configured and Power State Interface). Accordingly, power-efficient systems and methods to detect a mechanical shock event in information handling systems may be desired.

### SUMMARY

In accordance with the teachings of the present disclosure, the disadvantages and problems associated with detecting mechanical shock events in information handling systems during any sleep state may be reduced or eliminated.

In accordance with embodiments of the present disclosure, an information handling system may include a circuit board, a shock detector mounted on the circuit board, and a detection circuit electrically coupled to the shock detector. The shock detector may be configured to complete an electrical circuit in a first state in an absence of a threshold mechanical force applied to the information handling system and to have an impedance discontinuity in a second state in a presence of the threshold mechanical force. The detection circuit may be configured to detect whether the discontinuity exists.

In accordance with these and other embodiments of the present disclosure, a method may include completing an electrical circuit in a first state with a shock detector mounted on a circuit board in an absence of a threshold mechanical force applied to an information handling system. The method may also include creating an impedance discontinuity with the shock detector in a second state in a presence of the threshold mechanical force. The method may further include detecting, with a detection circuit electrically coupled to the shock detector, whether the impedance discontinuity exists.

In accordance with these and other embodiments of the present disclosure, an article of manufacture may include a computer readable medium and computer-executable instructions carried on the computer readable medium, the instructions readable by a processor, the instructions, when read and executed, for causing the processor to, in a detection circuit of an information handling system, determine if an impedance discontinuity exists in an electrical circuit. A shock detector may be mounted on a circuit board and may be configured to complete the electrical circuit in a first state in an absence of a threshold mechanical force applied to the information handling system and have an impedance discontinuity in a second state in a presence of the threshold mechanical force.

In accordance with these and other embodiments of the present disclosure a shock detector may include a first member and a second member. The first member may include a first hook, and the second member may include a second hook. The first member and the second member may be configured such that the first member mechanically couples to the second member via the first hook and the second hook in a first state such that the first member and the second member experience a spring tension force between one another and complete an electrical circuit. The first member and the second member may further be configured such that the first member mechanically uncouples from the second member in a second state to create an impedance discontinuity.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIGS. 2A and 2B illustrate side elevation views of an example shock detector of the example information handling system of FIG. 1, in accordance with embodiments of the present disclosure;

FIG. 3A illustrates a side elevation view of an example shock detector with varying sensitivity to mechanical shocks, in accordance with embodiments of the present disclosure;

FIGS. 3B and 3C each illustrate a perspective view of an example shock detector with varying sensitivity to mechanical shocks, in accordance with embodiments of the present disclosure; and

FIG. 4 illustrates a flow chart of an example method for detecting and processing a mechanical shock event in an example information handling system, in accordance with embodiments of the present disclosure.

### DETAILED DESCRIPTION

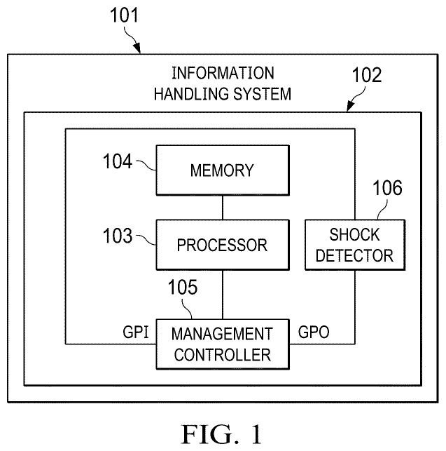

Preferred embodiments and their advantages are best understood by reference to FIGS. 1 through 4, wherein like numbers are used to indicate like and corresponding parts. For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

For the purposes of this disclosure, a circuit board may broadly refer to a printed circuit board (PCB), printed wiring board (PWB), printed wiring assembly (PWA) etched wiring board, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a block diagram of selected components of an example information handling system 101, in accordance with certain embodiments of the present disclosure. It is noted that the various components depicted in FIG. 1 may not be drawn to scale.

In some embodiments, information handling system 101 may comprise a server. In other embodiments, information handling system 101 may be a personal computer (e.g., a desktop computer, a laptop, notebook, tablet, handheld, smart phone, personal digital assistant, etc.). As depicted in FIG. 1, information handling system 101 may include a circuit board 102 (e.g., a motherboard or backplane) having mounted and/or formed thereon a processor 103, a memory 104 communicatively coupled to processor 103, a management controller 105 communicatively coupled to processor 103, and one or more shock detectors 106 electrically coupled to management controller 105.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 101.

Memory 104 may be communicatively coupled to processor 103 and may include any system, device, or apparatus configured to retain program instructions and/or data for a period of time (e.g., computer-readable media). Memory 104 may include RAM, EEPROM, a PCMCIA card, flash memory, magnetic storage, opto-magnetic storage, or any suitable selection and/or array of volatile or non-volatile memory that retains data after power to information handling system 101 is turned off.

Management controller 105 may be configured to provide out-of-band management facilities for management of information handling system 101. Such management may be made by management controller 105 even if information handling system 101 is powered off or powered to a standby state. Management controller 105 may include a processor, memory, out-of-band network interface separate from and physically isolated from an in-band network interface of information handling system 101, and/or other embedded information handling resources. In certain embodiments, management controller 105 may include or may be an integral part of a baseboard management controller (BMC) or a remote access controller (e.g., a Dell Remote Access Controller or Integrated Dell Remote Access Controller). In other embodiments, management controller 105 may include or may be an integral part of a chassis management controller (CMC). In yet other embodiments, management controller 105 may include or may be an integral part of an embedded controller (EC). Management controller 105 may include firmware comprising a program of executable instructions configured to be read and executed by management controller 105 in order to carry out the functionality of management controller 105, including functionality of management controller 105 described herein.

In addition to processor 103, memory 104, management controller 105, and shock detector 106, information handling system 101 may include one or more other information handling resources.

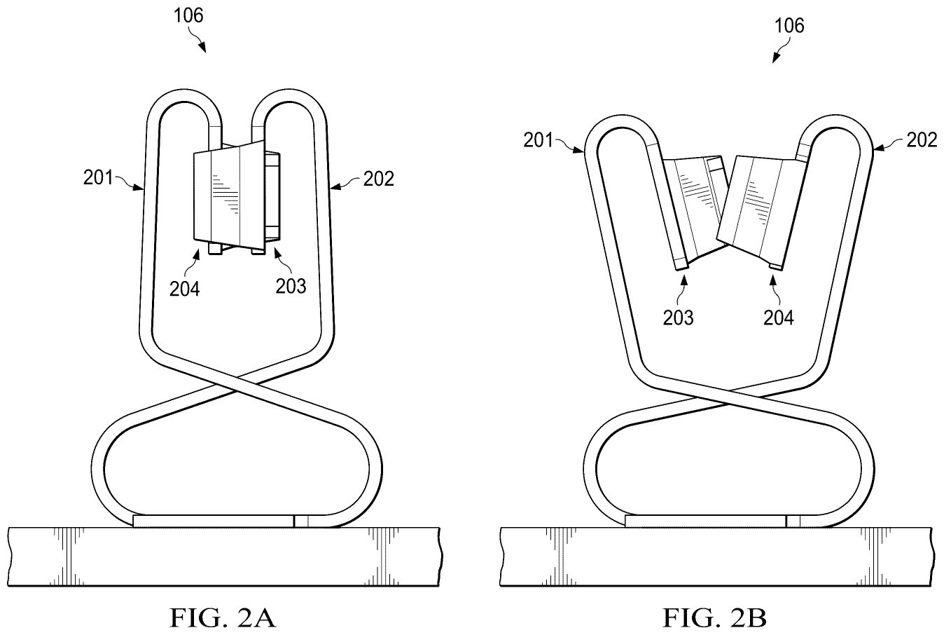

As shown in FIG. 1, one or more shock detectors 106 may be mounted on circuit board 102. FIGS. 2A and 2B illustrate side elevation views of selected components of an example shock detector 106 formed on circuit board 102, in accordance with embodiments of the present disclosure. As shown in FIGS. 2A and 2B, a shock detector 106 may comprise a first member 201 and a second member 202. In some embodiments, first member 201 and second member 202 may be springs. First member 201 may comprise a first hook 203, and second member 202 may comprise a second hook 204. As shown in FIG. 2A, in some embodiments first member 201 and second member 202 may be configured to mechanically couple with each other via first hook 203 and second hook 204 (i.e., first hook 203 and second hook 204 may be mechanically coupled in an “engaged” configuration) such that first member 201 and second member 202 experience spring tension force. As shown in FIG. 2B, in other embodiments first hook 203 and second hook 204 may not be mechanically coupled (i.e., in a “disengaged” configuration) such that first member 201 and second member 202 may not be mechanically coupled and experience no spring tension force. First member 201 and second member 202 may each experience a spring force that biases each member to the disengaged configuration in the absence of a countervailing force (e.g., the mechanical force of being engaged). As used herein, the “engaged” state may refer generally to any state other than the “disengaged” state. In some embodiments, shock detector 106 may be mounted on circuit board 102 (e.g., using surface mount technology printing).

Turning again to FIG. 1, shock detector 106 may be electrically coupled in a series configuration with a general-purpose output (GPO) pin of management controller 105 coupled to a first electrical node at one end of the series configuration and a general-purpose input (GPI) pin of management controller 105 coupled to a second electrical node at the other end of the series configuration.

In operation, if information handling system 101 experiences a mechanical shock that imparts a sufficient mechanical force to shock detector 106, first hook 203 may disengage from second hook 204 or vice-versa such that shock detector 106 experiences an impedance discontinuity (e.g., open circuit). In other words, if shock detector 106 experiences a threshold mechanical force, first hook 203 and second hook 204 may mechanically disengage, creating an impedance discontinuity. In order to detect whether such an impedance discontinuity has occurred, management controller 105 may output a known signal (e.g., logic high) on its GPO pin and determine if the same signal is received at its GPI pin. If the GPI pin receives the known signal, then management controller 105 may determine that no mechanical shock event has occurred. However, if the GPI pin does not receive the known signal, then management controller 105 may determine that a mechanical shock event has occurred. Although FIG. 1 depicts circuit board 102 having one shock detector 106 formed thereon, in some embodiments, a circuit board 102 may have any suitable number of shock detectors 106 formed thereon.

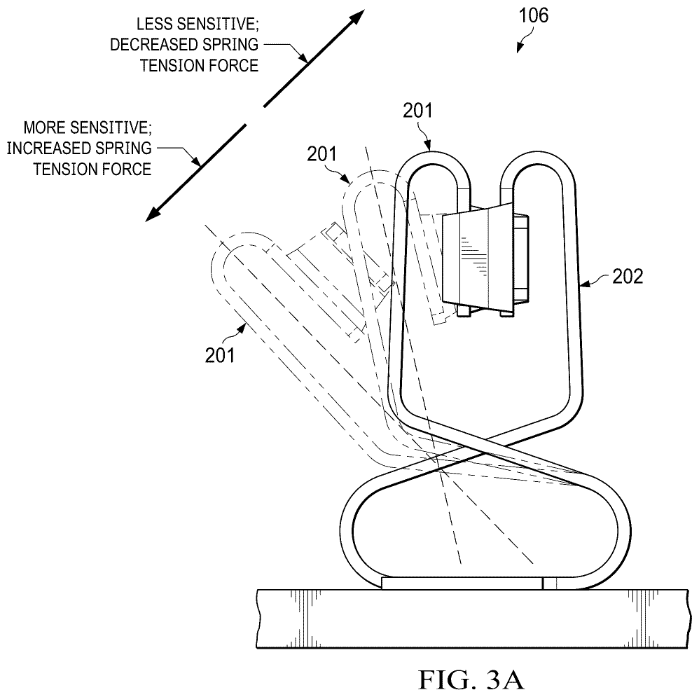

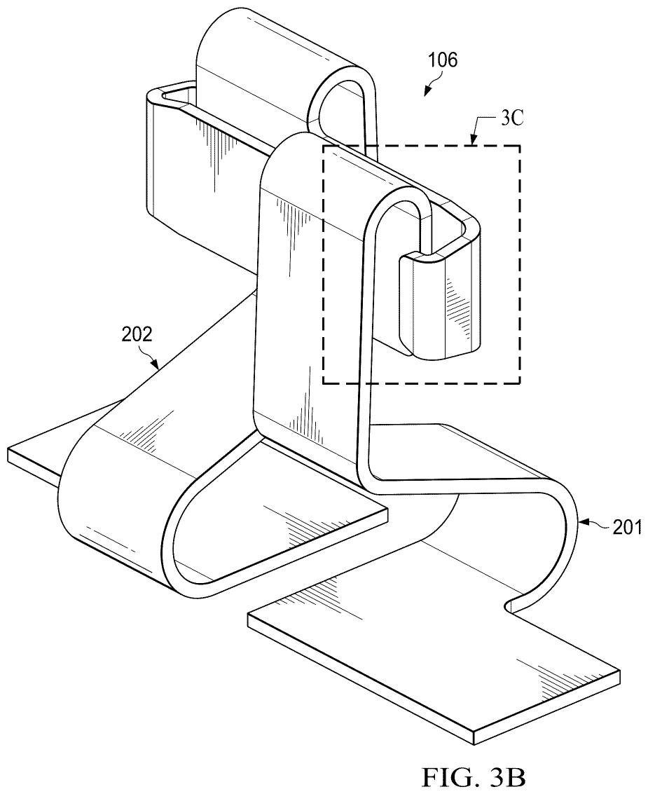

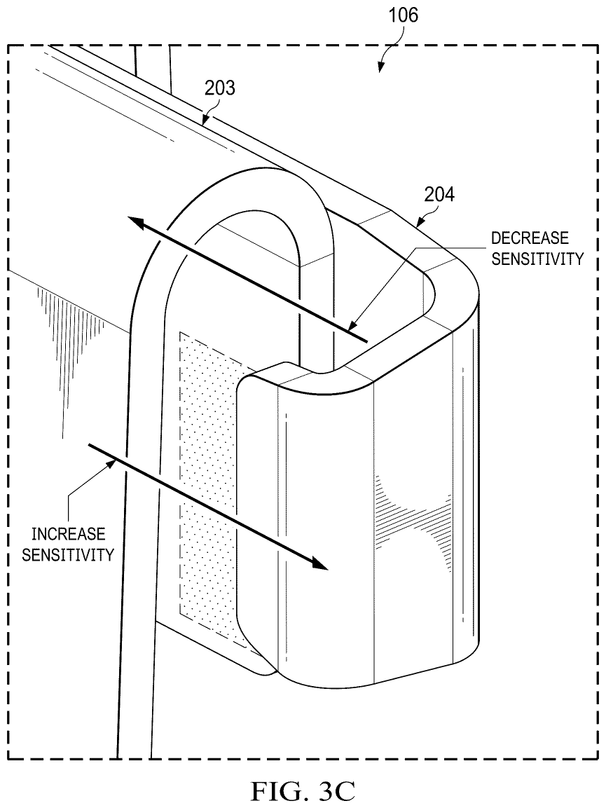

FIG. 3A illustrates a perspective view of selected components of an example shock detector 106 formed on circuit board 102, in accordance with embodiments of the present disclosure. As shown in FIG. 3A, a desired sensitivity of shock detector 106 may be configured by increasing or decreasing a spring tension force of either or both of first member 201 and second member 202, as sensitivity of shock detector 106 may be proportional to a spring tension of one or both of first member 201 and second member 202 of shock detector 106 in the engaged state.

FIGS. 3B and 3C illustrate side perspective views of selected components of an example shock detector 106 formed on circuit board 102, in accordance with embodiments of the present disclosure. As shown in FIGS. 3B and 3C, a desired sensitivity of a shock detector 106 may additionally or alternatively be configured by increasing or decreasing a mechanical resistance between a first hook 203 and a second hook 204, as sensitivity of a shock detector 106 may be inversely proportional to the mechanical resistance between first hook 203 and second hook 204.

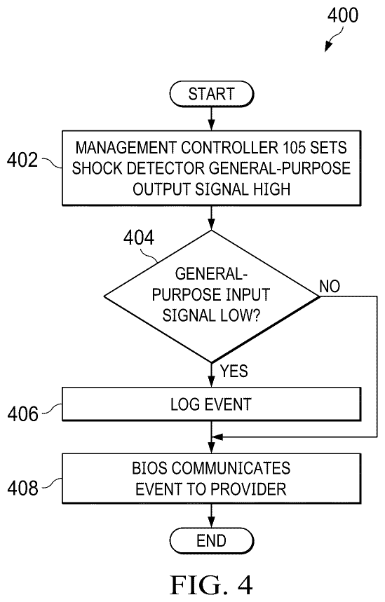

FIG. 4 illustrates a flow chart of an example method 400 for detecting and processing mechanical shock events on an information handling system 101, in accordance with embodiments of the present disclosure. According to certain embodiments, method 400 may begin at step 402. As noted above, teachings of the present disclosure may be implemented in a variety of configurations of information handling system 101 as shown in FIG. 1. As such, the preferred initialization point for method 400 and the order of the steps comprising method 400 may depend on the implementation chosen. In these and other embodiments, method 400 may be implemented as firmware, software, applications, functions, libraries, or other instructions.

At step 402, management controller 105 may set its GPO pin to a known signal (e.g., logic high). At step 404, management controller 105 may determine if the known signal is received at its GPI pin. If the GPI pin receives the known signal (e.g., logic high), no impedance discontinuity exists within shock detector 106, and method 400 may end. Otherwise if the GPI pin does not receive the known signal (e.g., logic low is received), then an impedance discontinuity may exist within shock detector 106, and method 400 may proceed to step 406.

At step 406, management controller 105 may log the mechanical shock event in a basic input/output system (BIOS) log. As a result, at step 408, the mechanical shock event may be communicated to a provider (e.g., manufacturer, vendor, etc.) of information handling system 102, who may determine if component failures are attributable to the mechanical shock event. After completion of step 408, method 400 may end.

Although FIG. 4 discloses a particular number of steps to be taken with respect to method 400, method 400 may be executed with greater or fewer steps than those depicted in FIG. 4. In addition, although FIG. 4 discloses a certain order of steps to be taken with respect to method 400, the steps comprising method 400 may be completed in any suitable order.

Method 400 may be implemented using information handling system 101, components thereof, or any other system such as that shown in FIG. 1 operable to implement method 400. In certain embodiments, method 400 may be implemented partially or fully in software and/or firmware embodied in computer-readable media.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a circuit board;
a shock detector mounted on the circuit board, the shock detector configured to complete an electrical circuit in a first state in an absence of a threshold mechanical force applied to the information handling system and to have an impedance discontinuity in a second state in a presence of the threshold mechanical force; and
a detection circuit electrically coupled to the shock detector and configured to detect whether the impedance discontinuity exists.

2. The information handling system of claim 1, wherein the shock detector comprises:
a first member comprising a first hook; and
a second member comprising a second hook;
wherein:
the first member and the second member are configured such that the first member mechanically couples to the second member via the first hook and the second hook in the first state such that the first member and the second member experience a spring tension force between one another and complete the electrical circuit; and
the first member and the second member are further configured such that the first member mechanically uncouples from the second member in the second state to create the impedance discontinuity.

3. The information handling system of claim 2, wherein the threshold mechanical force is proportional to the spring tension force between the first member and the second member in the first state.

4. The information handling system of claim 2, wherein the threshold mechanical force is inversely proportional to a mechanical resistance between the first member and the second member in the first state.

5. The information handling system of claim 1, wherein the detection circuit comprises a management controller configured to:
output a known signal on a first pin of the management controller electrically coupled to the shock detector;
receive an input signal on a second pin of the management controller electrically coupled to the shock detector; and
determine if the impedance discontinuity exists based on whether the input signal is equivalent to the known signal.

6. The information handling system of claim 5, wherein:
the first pin is a general-purpose output pin of the management controller; and
the second pin is a general-purpose input pin of the management controller.

7. The information handling system of claim 1, wherein the detection circuit is further configured to log an event associated with an occurrence of the impedance discontinuity.

8. A method comprising:
completing an electrical circuit in a first state with a shock detector mounted on a circuit board in an absence of a threshold mechanical force applied to an information handling system;
creating an impedance discontinuity with the shock detector in a second state in a presence of the threshold mechanical force; and
detecting, with a detection circuit electrically coupled to the shock detector, whether the impedance discontinuity exists.

9. The method of claim 8, wherein the shock detector comprises:
a first member comprising a first hook; and
a second member comprising a second hook;
wherein:
the first member and the second member are configured such that the first member mechanically couples to the second member via the first hook and the second hook in a first state such that the first member and second member experience a spring tension force between one another and complete the electrical circuit; and
the first member and the second member are further configured such that the first member mechanically uncouples from the second member in the second state to create the impedance discontinuity.

10. The method of claim 9, wherein the threshold mechanical force is proportional to the spring tension force between the first member and the second member in the first state.

11. The method of claim 9, wherein the threshold mechanical force is inversely proportional to a mechanical resistance between the first member and the second member in the first state.

12. The method of claim 8, further comprising:
outputting a known signal on a first pin of the management controller electrically coupled to the shock detector;
receiving an input signal on a second pin of the management controller electrically coupled to the shock detector; and
determining if the impedance discontinuity exists based on whether the input signal is equivalent to the known signal.

13. The method of claim 12, wherein:
the first pin is a general-purpose output pin of the management controller; and
the second pin is a general-purpose input pin of the management controller.

14. The method of claim 8, wherein the detection circuit is further configured to log an event associated with an occurrence of the impedance discontinuity.

15. An article of manufacture comprising:
a computer readable medium; and
computer-executable instructions carried on the computer readable medium, the instructions readable by a processor, the instructions, when read and executed, for causing the processor to, in a detection circuit of an information handling system:
determine if an impedance discontinuity exists in an electrical circuit, wherein a shock detector mounted on a circuit board is configured to complete the electrical circuit in a first state in an absence of a threshold mechanical force applied to the information handling system and have an impedance discontinuity in a second state in a presence of the threshold mechanical force.

16. The article of claim 15, the instructions for further causing the processor to:
output a known signal on a first pin of a management controller electrically coupled to the shock detector;
receive an input signal on a second pin of the management controller electrically coupled to the shock detector; and
determine if the impedance discontinuity exists based on whether the input signal is equivalent to the known signal.

17. The article of claim 16, wherein:
the first pin is a general-purpose output pin of the management controller; and
the second pin is a general-purpose input pin of the management controller.

18. The article of claim 15, the instructions for further causing the processor to log an event associated with an occurrence of the impedance discontinuity.

19. A shock detector comprising:
a first member comprising a first hook; and
a second member comprising a second hook;
wherein:
the first member and the second member are configured such that the first member mechanically couples to the second member via the first hook and the second hook in a first state such that the first member and the second member experience a spring tension force between one another and complete an electrical circuit; and
the first member and the second member are further configured such that the first member mechanically uncouples from the second member in a second state to create an impedance discontinuity.

20. The shock detector of claim 18, wherein a threshold mechanical force is proportional to the spring tension force between the first member and the second member in the first state.

21. The shock detector of claim 18, wherein a threshold mechanical force is inversely proportional to the spring tension force between the first member and the second member in the second state.
